(19) United States
(12) Patent Application Publication
(10) Pub. No.: US 2024/0272862 A1
(43) Pub. Date: Aug. 15, 2024

(54) Digital Bumper Sticker

(71) Applicant: David Tobias, Arvada, CO (US)

(72) Inventor: David Tobias, Arvada, CO (US)

(21) Appl. No.: 18/434,469

(22) Filed: Feb. 6, 2024

Related U.S. Application Data
(60) Provisional application No. 63/484,145, filed on Feb. 9, 2023.

(51) Int. Cl. G06F 3/147; G09F 9/33; G09F 9/35; G09F 21/04; H05K 5/00; H05K 5/02

(52) U.S. Cl. CPC G06F 3/147; G09F 9/33; G09F 9/35; G09F 21/041; G09F 21/048; H05K 5/0018; H05K 5/0204

(57) ABSTRACT

The present invention is a digital display system comprising a display device configured for attachment to a vehicle and a controller device that can wirelessly control the display device. Said display device further comprises a casing, a screen contained within said casing, an attachment mechanism connected to the rear of said casing, a processor, and a wireless receiver. Said controller device further comprises a body, a wireless transmitter, at least one indicator light, at least one interactive component, and a processor. The digital bumper sticker overcomes the shortcomings of similar vehicle customizations by allowing a user to alter the message or design being displayed on their vehicle at any time. A user can wirelessly alter the message or design bring displayed on the display device using the controller device.

### FIELD OF THE INVENTION

The present invention relates generally to digital display systems. Particularly, the present invention is a digital display system comprising a display device configured for attachment to a vehicle and a controller device that can wirelessly control the display device.

### BACKGROUND OF THE INVENTION

Customizations are often added to vehicles to display advertising messages, personal messages, and other various designs. Commonly, these displays are done through bumper stickers adhered to a vehicle or designs more permanently placed by paint or billboard-style attachments. While each of these methods allow a user to display images or messages on their vehicle, they cannot be easily changed and may be ineffective in catching the attention of passersby.

The present invention overcomes the shortcomings of similar vehicle customizations by allowing a user to alter the message or design being displayed on their vehicle at any time.

### SUMMARY OF THE INVENTION

The present invention digital vehicle display system comprising a controller and a display. The controller comprises a wireless transmitter and the display comprises a wireless receiver, allowing the controller and display to be placed in wireless communication with one another. Through this communication, the display may be activated, and in some cases controlled, by interacting with components of the controller. The display comprises a screen for displaying media such as photos, videos, words, advertisements, and designs. Media and other data may be stored directly on the display using an internal storage device, or may be removably connected to the display by external storage devices such as memory cards. The display is removable from a vehicle, allowing it to be stored inside the vehicle to prevent theft. Further, the display may be activated and controlled only by a user having possession of the controller.

### BRIEF DESCRIPTION OF THE DRAWINGS

FIG. 1 is a top front isometric view of the display of the present invention in accordance with at least one embodiment.

FIG. 2 is a front elevation view of the display of the present invention in accordance with at least one embodiment.

FIG. 3 is a rear elevation view of the display of the present invention in accordance with at least one embodiment.

FIG. 4 is a bottom plan view of the display of the present invention in accordance with at least one embodiment.

FIG. 5 is an exploded top front isometric view of the display of the present invention in accordance with at least one embodiment.

FIG. 6 is a top front isometric view of the controller of the present invention in accordance with at least one embodiment.

FIG. 7 is a front elevation view of the controller of the present invention in accordance with at least one embodiment.

FIG. 8 is a side elevation view of the controller of the present invention in accordance with at least one embodiment.

FIG. 9 is a component diagram showing the connections between internal components of the present invention in accordance with at least one embodiment.

FIG. 10 is an illustration of the present invention attached to a vehicle.

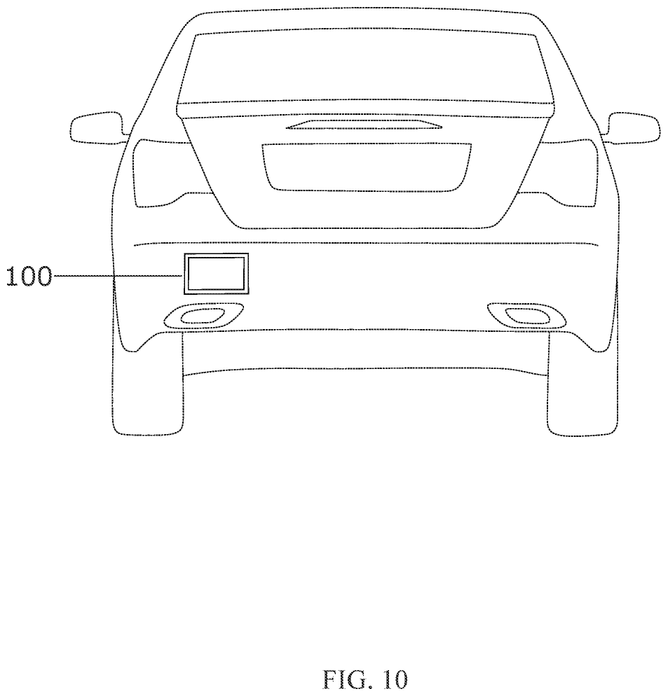

### DETAILED DESCRIPTION OF THE INVENTION

All illustrations of the drawings are for the purpose of describing selected versions of the present invention and are not intended to limit the scope of the present invention.

The present invention is a digital vehicle display system comprising a controller device and a display device. In use, the display device is attached to a vehicle or other surface and the controller device wirelessly communicates with the display device to activate and otherwise control the display device.

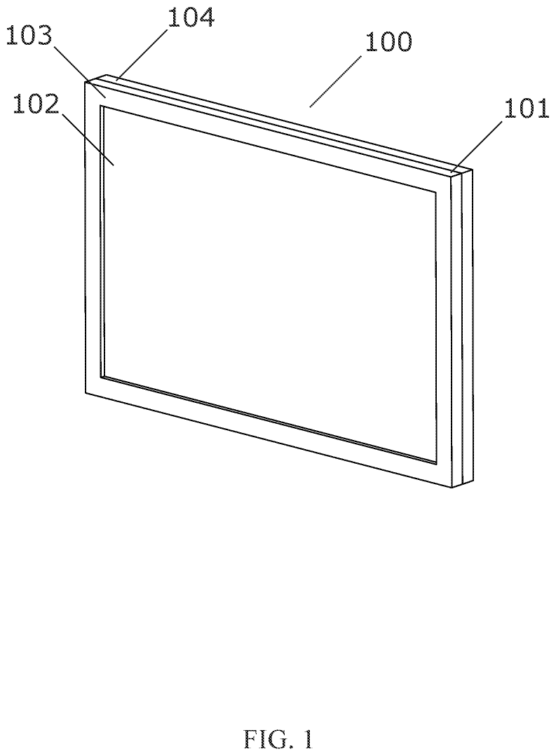

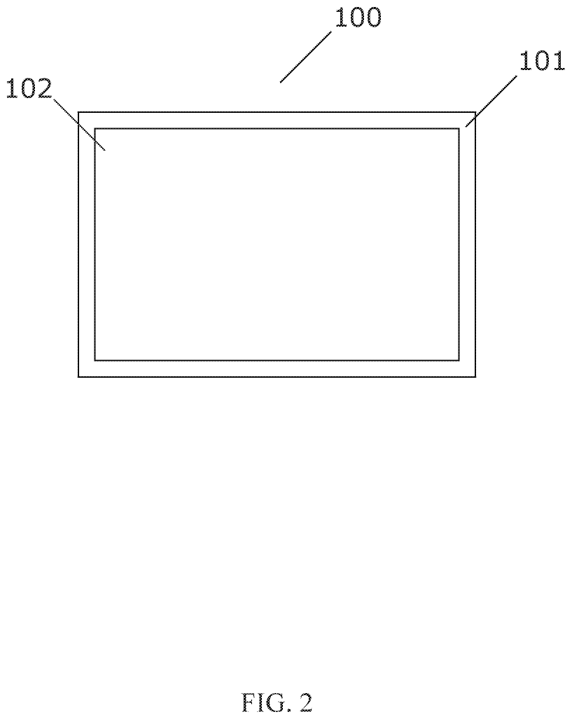

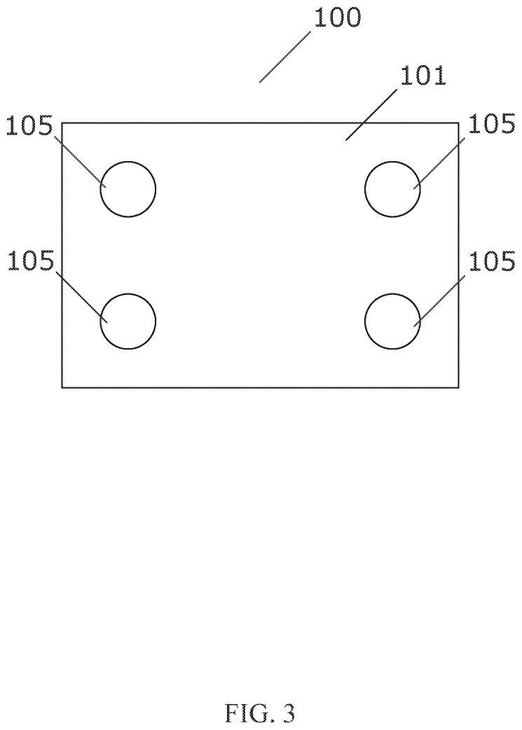

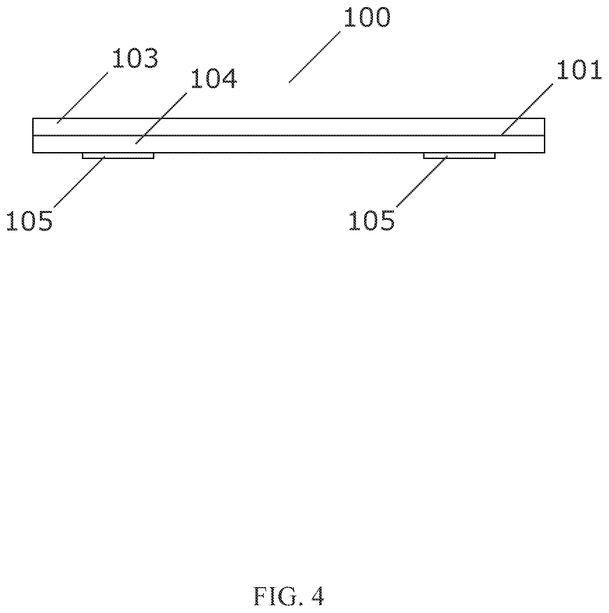

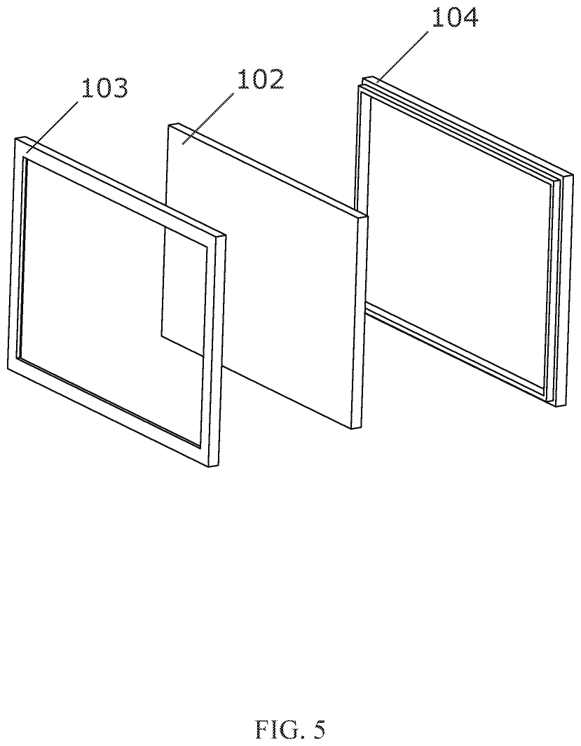

Referring to FIG. 1-5, the display device 100 of the present invention comprises a casing 101, a screen 102, an attachment mechanism 105, a processor, and a wireless receiver. The casing preferably comprises a front panel 103 and a rear panel 104. The screen 102 is positioned between the front panel 103 and the rear panel 104 and is visible through the front panel 103. The screen 102 is preferably a liquid crystal display (LCD), though it may instead be an LED display or other type of digital display. The attachment mechanism 105 is connected to the rear panel 104 of the casing 101 and is configured to secure the casing 101 to a vehicle or other surface. In the preferred embodiment, the attachment mechanism 105 is at least one magnet, allowing the display 100 to be removed and reattached efficiently, though the attachment mechanism 105 may instead be an adhesive, screws or bolts, or other similar components. The wireless receiver is configured to receive signals from the controller or other devices, matching the signal type of the controller, whether that be radio frequencies, Bluetooth, infrared, or other wireless communication. The processor is configured to facilitate activation and media display on the screen. In some embodiments, the display 100 may further comprise a storage device configured to store media on the display. The storage device may be connected to the wireless receiver to receive data or media from the controller or other signal and may also be connected to the screen 102 to display the stored media. Alternatively, the storage device may be connected to an external storage component such as an SD card, flash drive, or other storage technology.

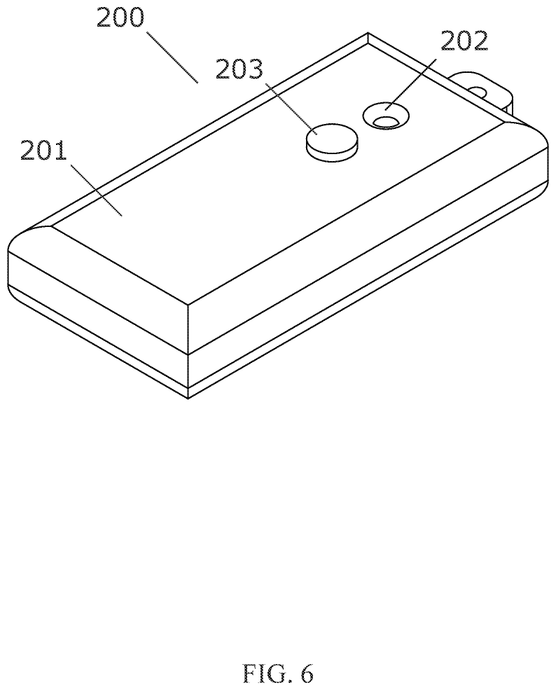

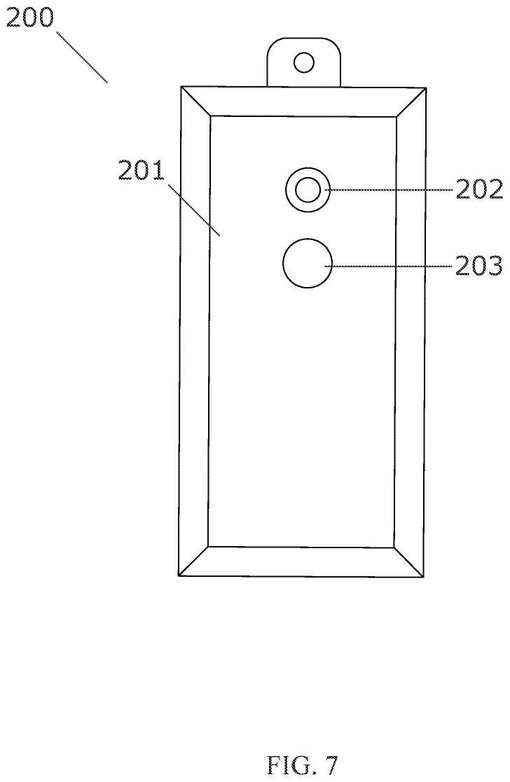

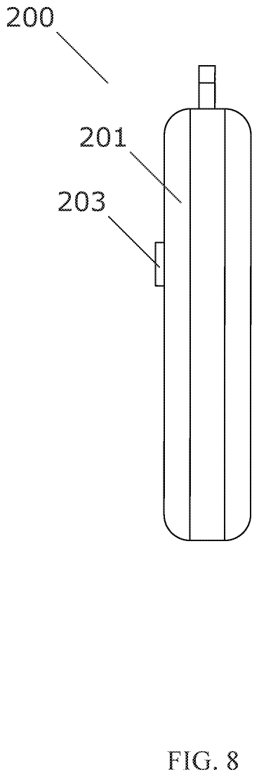

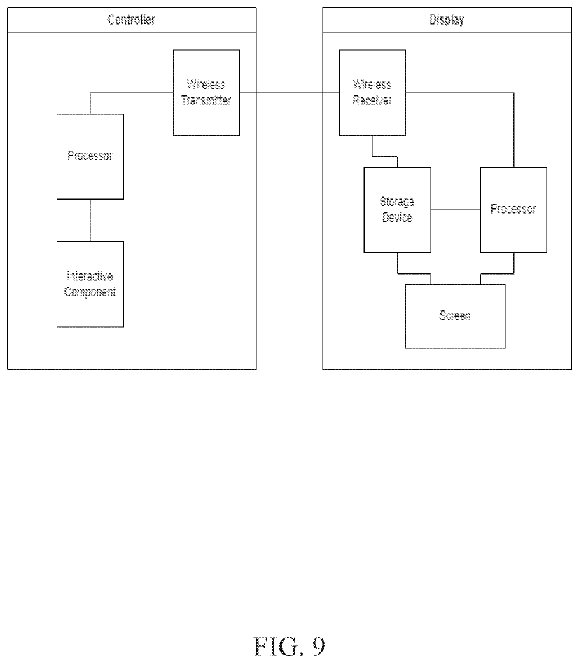

Referring to FIG. 6-8, the controller 200 of the present invention comprises a body 201 and a wireless transmitter. The wireless transmitter is preferably a short range radio transmitter utilizing RFID technology, though the wireless transmitter may also operate by way of Wi-Fi, Bluetooth, infrared communication, or other wireless communication systems. In one embodiment, the controller 200 acts merely like a key, triggering activation of the display by physical proximity. In other embodiments of the present invention, the controller 200 may further comprise at least one indicator light 202 and at least one interactive component 203. The at least one indicator light 202 may activate to alert the user of certain operations of the system such as when the controller 200 is close enough to the display to function or when the display has been activated, among other indications. The at least one interactive component 203 may include a power button 203, a media control interface, and other mechanisms for remotely controlling the display. The power button 203 may be used to activate and deactivate the display, while the media control interface may be used to change the image shown on the display. The at least one interactive component 203 is preferably one or more buttons, though it may also comprise knobs, dials, switches, touchscreens, or any other interactive components. The controller 200 may further comprise a processor for facilitating communication of media with the display. Communication of media within the devices of the present invention and between the devices of the present invention are shown in one embodiment in FIG. 9.

In use, the display 100 is attached to a vehicle or other surface by the attachment mechanism 105. The display 100 is preferably attached on the rear of the vehicle, such as the bumper of a car, but may also be attached to the sides, front, and top of the vehicle or may be attached inside the vehicle. Once secured, the controller 200 may be used to activate the display. In one embodiment, the display 100 is automatically activated by radio communication between the wireless transmitter of the controller 200 and the wireless receiver of the display 100. This wireless radio connection may utilize RFID technology to ensure that the user in possession of the controller 200 is the only one able to activate the display 100. In alternative embodiments, the user may activate the display 100 by interacting with the at least one interactive component 203 of the controller 200. This may include switching between media saved on the storage device of the display 100, downloading data or media to the storage device, or otherwise manipulating the status of the display 100. Media stored on the display 100 will be shown on the screen 102 as preprogrammed or as determined by use of the controller 200.

Although the invention has been explained in relation to its preferred embodiment, it is to be understood that many other possible modifications and variations can be made without departing from the spirit and scope of the invention.

What is claimed is:

1. A display device comprising:
a casing,
a screen contained within said casing,
an attachment mechanism connected to the rear of said casing,
a processor, and
a wireless receiver,
wherein said screen is visible through the front of said casing;
wherein said casing can be affixed to a surface using said attachment mechanism;
wherein said processor is configured to facilitate activation and media display on said screen; and
wherein said wireless receiver is configured to receive signals wirelessly from a controller device and match the signal type from said controller device.

2. The display device of claim 1,
wherein said casing further comprises a front panel and a rear panel.

3. The display device of claim 1,
wherein said screen is a liquid-crystal display (LCD) for video display.

4. The display device of claim 1,
wherein said screen uses light-emitting diodes (LED) as pixels for video display.

5. The display device of claim 1,
wherein said attachment mechanism further comprises of at least one magnet.

6. The display device of claim 1,
wherein said attachment mechanism further comprises of adhesive.

7. The display device of claim 1,
wherein said attachment mechanism further comprises of at least one screw.

8. The display device of claim 1,
wherein said attachment mechanism further comprises of at least one bolt.

9. The display device of claim 1,
wherein said wireless receiver can receive radio frequencies and signals.

10. The display device of claim 1,
wherein said wireless receiver can receive short-range wireless Bluetooth frequencies and signals.

11. The display device of claim 1,
wherein said wireless receiver can receive infrared frequencies and signals.

12. The display device of claim 1, further comprising:
a storage device.

13. The display device of claim 12,
wherein said storage device is connected to said wireless receiver to receive data or media from a controller device.

14. The display device of claim 12,
wherein said storage device is connected to said screen to display stored media.

15. The display device of claim 12,
wherein said storage device is connected to an external storage component.

16. A controller device comprising:
a body,
a wireless transmitter,
at least one indicator light,
at least one interactive component,
a processor,
wherein said wireless transmitter is configured to send signals wirelessly to a display device;
wherein said indicator light may activate to alert a user of certain operations of the system such as when the controller device is close enough to a display device to function and when said display device has been activated, and
wherein said processor is configured to facilitate communication of media with a display device.

17. The controller device of claim 16,
wherein said interactive component further comprises a power button, and
wherein said power button is configured to activate and deactivate a display device.

18. The controller device of claim 16,
wherein said interactive component further comprises a media control interface, and
wherein said media control interface is configured to change media shown on a display device.

19. The controller device of claim 16,
wherein said interactive component further comprises a plurality of knobs, dials, switches, and touchscreens, and
wherein said plurality of knobs, dials, switches, and touchscreens facilitate wireless control of a display device.

20. A digital vehicle display system comprising:
a display device,
a controller device,
wherein said display device further comprises a casing,
a screen contained within said casing,
an attachment mechanism connected to the rear of said casing,
a processor,
a wireless receiver,
wherein said screen is visible through the front of said casing;
wherein said casing can be affixed to a surface using said attachment mechanism;
wherein said processor is configured to facilitate activation and media display on said screen;
wherein said wireless receiver is configured to receive signals wirelessly from a controller device and match the signal type from said controller device; and
wherein said controller device further comprises a body,
a wireless transmitter,
at least one indicator light,
at least one interactive component,
a processor,
wherein said wireless transmitter is configured to send signals wirelessly to a display device;
wherein said indicator light may activate to alert a user of certain operations of the system such as when the controller device is close enough to a display device to function and when said display device has been activated; and
wherein said processor is configured to facilitate communication of media with a display device.
